(19) United States
(12) Patent Application Publication
(10) Pub. No.: US 2007/0184613 A1
(43) Pub. Date: Aug. 9, 2007

(54) Phase change RAM including resistance element having diode function and methods of fabricating and operating the same

(75) Inventors: Ki-Joon Kim, Yongin-si (KR); Yoon-Ho Khang, Yongin-si (KR); Jin-Seo Noh, Seoul (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/703,126

(22) Filed: Feb. 7, 2007

(30) Foreign Application Priority Data
Feb. 7, 2006 (KR) 10-2006-0011830

(51) Int. Cl. H01L 21/336

(52) U.S. Cl. 438/257; 365/211; 438/593

(57) ABSTRACT

A phase change RAM (PRAM) including a resistance element having a diode function, and methods of fabricating and operating the same are provided. The PRAM may include a substrate, a phase change diode layer formed on the substrate and an upper electrode formed on the phase change diode layer. The phase change diode layer may include a material layer doped with first impurities, and a phase change layer which is stacked on the doped layer. The phase change layer may show characteristics of a semiconductor material doped with impurities having an opposite conductive type to that of the first impurities.

### PRIORITY STATEMENT

This application claims priority under 35 U.S.C. §119 to Korean Patent Application No. 10-2006-0011830, filed on Feb. 7, 2006, in the Korean Intellectual Property Office (KIPO), the entire contents of which are incorporated herein by reference.

### BACKGROUND

1. Field

Example embodiments relate to a semiconductor memory device and methods of fabricating and operating the same. Other example embodiments relate to a phase change RAM including a phase change resistance element having diode function and methods of fabricating and operating the same.

2. Description of the Related Art

A non-volatile memory device has the advantages of a DRAM. As information technology is developed, and various equipment and contents are developed in order to meet the needs for the development of information technology, a demand of non-volatile memory devices may increase. To satisfy the market changes, various non-volatile memory devices have been introduced after typical flash and/or SONOS memory devices.

One of the non-volatile memory devices used at present may be a phase change RAM (PRAM) that may be placed in lead along with a magnetic RAM (MRAM), a ferroelectric RAM (FRAM) and/or a resistance RAM (RRAM). The unit cell of a PRAM may include one resistance element composed of a phase change material and one transistor flowing current to the resistance element or cutting off the current, but there has been introduced a PRAM in which the transistor is replaced with a diode, for example, including one resistance element and one diode, in order to increase integration density. While the PRAM (hereinafter, conventional PRAM) may not have the defects of a conventional memory device, it may be necessary to modify the structure of the PRAM capable of further simplifying fabrication processes and increasing an integration density thereof when considering the speed of the current technology development of industries.

### SUMMARY

Example embodiments provide a phase change RAM (PRAM) having a more simplified structure capable of simplifying fabrication processes of the PRAM and increasing an integration density thereof. Example embodiments also provide a method of operating the PRAM and a method of fabricating the PRAM.

According to example embodiments, a PRAM may include a substrate, a phase change diode layer on the substrate and an upper electrode on the phase change diode layer.

The phase change diode layer may include a material layer doped with first impurities, and a phase change layer, which are sequentially stacked, wherein the phase change layer shows characteristics of a semiconductor material doped with impurities having an opposite conductive type to that of the first impurities. The first impurities may be n-type impurities, and the phase change layer may be composed of a phase change material showing p-type semiconductor material characteristics.

According to example embodiments, the PRAM may further include a word line between the phase change diode layer and the substrate, and a bit line on the upper electrode to contact the upper electrode and to cross the word line. According to example embodiments, the PRAM may further include a word line on the substrate spaced from the phase change diode layer, and a bit line on the upper electrode to contact the upper electrode and to cross the word line. A width of the phase change layer may be equal to or greater than a width of the material layer doped with first impurities.

According to example embodiments, the phase change diode layer may include a phase change layer and a material layer doped with first impurities, which may be sequentially stacked, in which the phase change layer may be composed of a phase change material showing characteristics of a semiconductor material doped with impurities having an opposite conductive type to that of the first impurities. The first impurities may be n-type impurities, and the phase change layer may be composed of a phase change material showing p-type semiconductor material characteristics. The substrate may be an n-type or a p-type semiconductor substrate, and may be a non-semiconductor substrate. According to other example embodiments, the first impurities may be p-type impurities, and the phase change layer may be composed of a phase change material showing n-type semiconductor material characteristics.

According to example embodiments, a method of operating a PRAM may include providing a phase change diode layer between a substrate and a first interconnection and applying a current through the phase change diode layer between the substrate and the first interconnection in a forward direction. In the operating method, applying the current may include applying one from the group consisting of a write current, a read current, and an erase current. Applying the read current may further include applying the read current to measure a resistance of the phase change diode layer, and comparing the measured resistance to a reference resistance.

According to example embodiments, a method of fabricating a PRAM may include forming a first interconnection on a substrate doped with first impurities, forming a first insulating interlayer on the substrate, to cover the first interconnection, exposing a portion of the substrate spaced from the first interconnection by forming a contact hole in the first insulating interlayer, filling the contact hole with a material layer doped with first impurities, sequentially stacking a phase change layer and an upper electrode on the first insulating interlayer to cover the doped material layer, the phase change layer showing semiconductor characteristics opposite to that of the doped material layer and forming a second interconnection connected to the upper electrode and crossing the first interconnection.

Sequentially stacking a phase change layer and an upper electrode may include forming a second insulating interlayer on the first insulating interlayer, to cover the doped material layer, forming a photoresistive layer pattern on the second insulating interlayer defining a portion where the phase change layer is formed, forming a via hole exposing the doped material layer in the second insulating interlayer, using the photoresistive layer pattern as a mask, sequentially stacking the phase change layer and the upper electrode in the via hole and removing the photoresistive layer pattern. The first impurities may be n-type impurities, and the phase change layer may be composed of a phase change material showing p-type semiconductor material characteristics.

According to example embodiments, a method of fabricating a PRAM may include forming a first interconnection on a substrate doped with first impurities, forming an insulating interlayer on the substrate, to cover the first interconnection, exposing a portion of the substrate spaced from the first interconnection by forming a contact hole in the insulating interlayer, sequentially stacking a material layer doped with the first impurities, a phase change layer showing semiconductor characteristics opposite to that of the doped material layer, and an upper electrode in the contact hole and forming a second interconnection on the insulating interlayer, the second interconnection connected to the upper electrode and crossing the first interconnection.

In the fabricating method, the first impurities may be n-type impurities, and the phase change layer may be composed of a phase change material showing p-type semiconductor material characteristics. The material layer doped with the first impurities, and the phase change layer may be formed using different methods, and the material layer doped with the first impurities may be formed using a selective epitaxial growth method.

According to example embodiments, a method of fabricating a PRAM may include forming a first interconnection on a substrate doped with first impurities, forming an insulating interlayer on the substrate, to cover the first interconnection, exposing a portion of the substrate spaced from the first interconnection by forming a contact hole in the insulating interlayer, sequentially forming a phase change layer and a material layer doped with second impurities having a conductivity type opposite to that of the first impurities, in the contact hole and forming a second interconnection connected to the doped material layer and crossing the first interconnection, on the insulating interlayer, wherein the phase change layer is composed of a phase change material showing semiconductor characteristics opposite to that of the substrate. In the fabricating method, the first interconnection may be formed to be buried or embossed on the substrate.

According to example embodiments, a method of fabricating a PRAM may include forming a first interconnection on a substrate doped with first impurities, forming an insulating interlayer on the substrate, to cover the first interconnection, exposing a portion of the substrate spaced from the first interconnection by forming a contact hole in the insulating interlayer, sequentially forming a phase change layer and a material layer doped with second impurities having a conductivity type opposite to that of the first impurities, in the contact hole and forming a second interconnection connected to the doped material layer and crossing the first interconnection, on the insulating interlayer, wherein the phase change layer is composed of a phase change material showing the same semiconductor characteristics as that of the substrate. In the fabricating method, a conductive layer may be further formed between the substrate and the phase change layer. The method may further include forming a conductive plug between the first interconnection and the substrate.

### BRIEF DESCRIPTION OF THE DRAWINGS

Example embodiments will be more clearly understood from the following detailed description taken in conjunction with the accompanying drawings. FIGS. 1-26 represent non-limiting, example embodiments as described herein.

FIG. 1 is an equivalent circuit of a phase change RAM (PRAM) according to example embodiments;

FIGS. 2A and 2B are diagrams illustrating a structure of the PRAM having the equivalent circuit of FIG. 1 according to example embodiments;

FIG. 3 is a diagram illustrating a structure of the PRAM having the equivalent circuit of FIG. 1 according to example embodiments;

FIG. 4 is a diagram illustrating a structure of the PRAM having the equivalent circuit of FIG. 1 according to example embodiments;

FIGS. 5A and 5B are diagrams illustrating structures of PRAMs employing technical characteristics of the PRAM of FIG. 4 to the PRAM of FIG. 2;

FIG. 6 is a diagram illustrating a structure of a PRAM having the equivalent circuit of FIG. 1 according to example embodiments;

FIG. 7 is a three-dimensional view illustrating that the first interconnection functioning as a bit line in the PRAM of FIG. 6 is formed in the substrate with a recessed shape;

FIG. 8 is a three-dimensional view illustrating that the first interconnection functioning as a bit line in the PRAM of FIG. 6 is formed in the substrate with a raised shape;

FIG. 9 is a diagram illustrating that the conductive layer, the phase change layer and the conductive plug in the PRAM of FIG. 6 all may have a same diameter;

FIG. 10 illustrates plots of current-voltage characteristics measured with respect to four specimens to verify that the lower electrode contact layer and the phase change layer in the PRAM according to example embodiments show P-N junction diode characteristics;

FIG. 11 illustrates current-voltage characteristics measured with respect to the specimen whose phase change layer is removed;

FIGS. 12-15 are diagrams to explain a method of operating a PRAM according to example embodiments in accordance with processing sequences;

FIGS. 16-22 are diagrams to explain a method of fabricating the PRAM of FIG. 3 in accordance with processing sequences, and

FIGS. 23-26 are diagrams to explain a method of fabricating the PRAM of FIG. 4 in accordance with processing sequences.

### DETAILED DESCRIPTION OF EXAMPLE EMBODIMENTS

Hereinafter, a phase change RAM including a phase change resistance element having a diode function, and methods of fabricating and operating the same according to example embodiments will be explained in detail with reference to the accompanying drawings. In the drawings, the thicknesses of layers and regions are exaggerated for clarity.

Spatially relative terms, such as “beneath,” “below,” “lower,” “above,” “supper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90° or at other orientations) and the spatially relative descriptors used herein interpreted accordingly.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A phase change RAM according to example embodiments will be explained. FIG. 1 illustrates an equivalent circuit of a phase change RAM (PRAM) according to example embodiments. Referring to FIG. 1, a PRAM according to example embodiments may include one phase change diode 30. The phase change diode 30 may include an n-type semiconductor layer 30a and a p-type phase change layer 30b, and may be a diode showing the same current-voltage characteristics as that of a typical PN junction diode. The n-type semiconductor layer 30a and the p-type phase change layer 30b may be sequentially stacked in the phase change diode 30. The p-type phase change layer 30b of the phase change diode 30 may be connected to a bit line BL. The n-type semiconductor layer 30a may be connected to a word line WL. The n-type semiconductor layer 30a may be, for example, a silicon layer doped with n-type impurities.

The p-type phase change layer 30b may be a compound layer including, for example, tellurium (Te), showing p-type semiconductor characteristics. The compound layer including tellurium may be a Ge—Sb—Te layer, a Te—Ge—Sn—Au layer, a Bi—Sb—Te layer, a Bi—Sb—Te—Se layer, an In—Sb—Te layer or a Sb—Se layer. The Ge—Sb—Te layer may be, for example, a Ge₂Sb₂Te₅ layer or a GeSb₂Te₄ layer. The Bi—Sb—Te—Se layer may be, for example, a Sb₂Te₃—Bi₂Se₃ layer. The In—Sb—Te layer may be a In₃SbTe₂ layer. The Sb—Se layer may be, for example, a Sb₂Se layer.

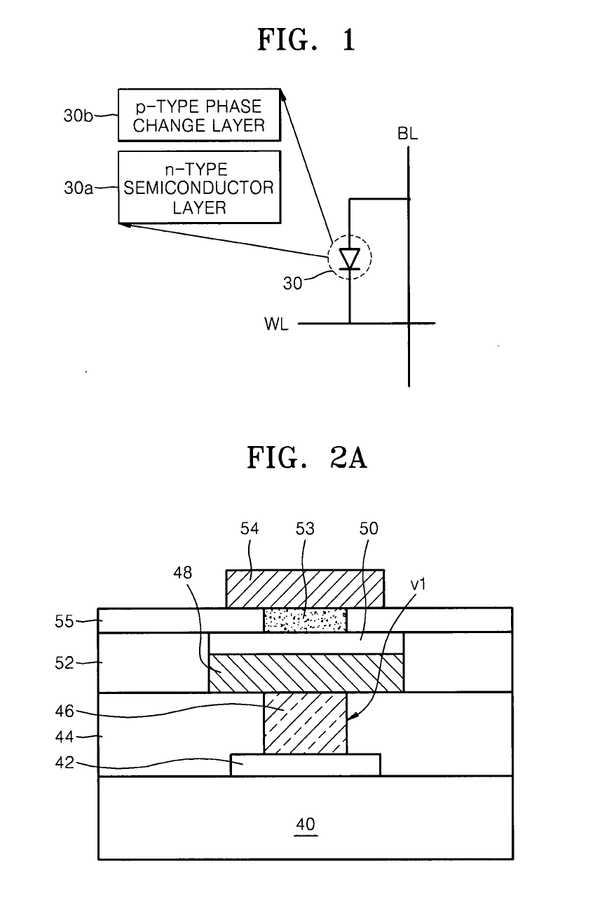

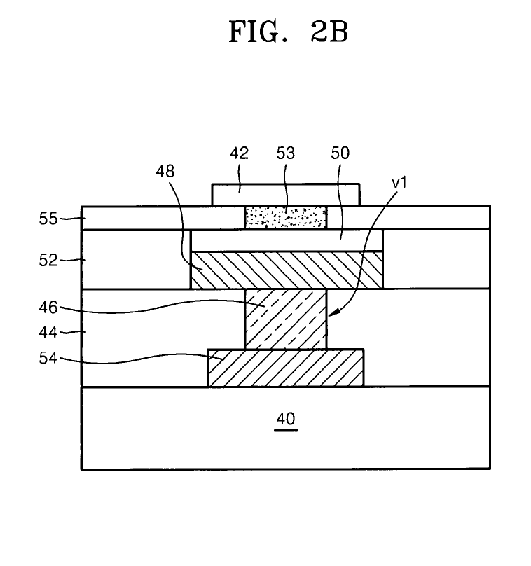

FIG. 2A illustrates a structure of the PRAM having the equivalent circuit of FIG. 1 according to example embodiments. Referring to FIG. 2A, a first interconnection 42 may be formed on a predetermined or given portion of a substrate 40. The substrate 40 may be a typical semiconductor substrate, an SOI substrate and/or a nonconductive substrate. The first interconnection 42 may be a conductive interconnection and may be used as a lower electrode and a word line as well. A first insulating interlayer 44 having a via hole v1 exposing the first interconnection 42 may be formed on the substrate 40. The via hole v1 may be filled with a conductive plug 46. The conductive plug 46 may be a lower electrode contact plug and may be formed of an n-type semiconductor. The conductive plug 46 may correspond to the n-type semiconductor layer 30a of FIG. 1. A phase change layer 48 and an upper electrode 50 may be sequentially stacked on the first insulating interlayer 44, to cover the conductive plug 46.

The phase change layer 48 may be composed of a material having the same characteristics as that of a p-type semiconductor, and may be, for example, a GST layer. The upper electrode 50 may be any one selected from the group consisting of Ti—N, Ti—Al—N, W—N, Ti—W, and Ti—Te electrodes or may be formed of at least two electrodes thereof. The phase change layer 48 and the upper electrode 50 may be surrounded by a second insulating interlayer 52. The second insulating interlayer 52 may be composed of the same material as that of the first insulating interlayer 44 disposed therebelow. An upper electrode contact plug 53 may be disposed on the upper electrode 50, and the upper electrode contact plug 53 may be surrounded by a third insulating interlayer 55. The third insulating interlayer 55 may be composed of a material identical to or different from that of the second insulating interlayer 52. A second interconnection 54 may be disposed on the third insulating interlayer 55 to cover the upper electrode contact plug 53. The second interconnection 54 may be disposed in the direction crossing or in parallel with the first interconnection 42. The second interconnection 54 may be a bit line.

The positions of the first and second interconnections 42 and 54 may be changed as shown in FIG. 2B. The first interconnection 42 may be disposed on the third insulating interlayer 55, to cover the upper electrode contact plug 53. The second interconnection 55 may be disposed between the substrate 40 and the conductive plug 46. In the case of FIG. 2B, the first and second interconnections 42 and 54 may cross or may be parallel to each other.

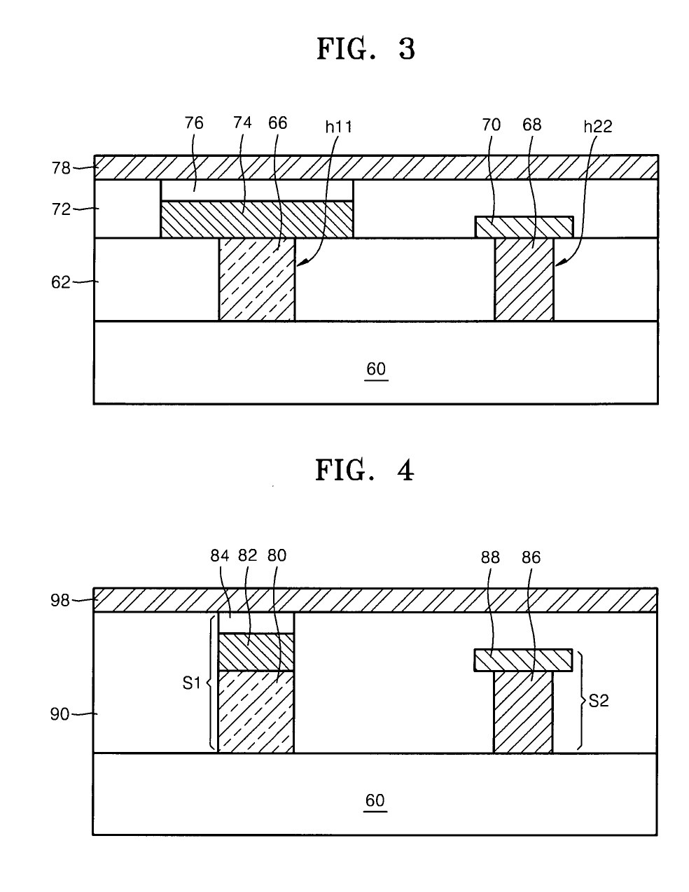

FIG. 3 illustrates a structure of the PRAM having the equivalent circuit of FIG. 1 according to example embodiments. Referring to FIG. 3, a first insulating interlayer 62 may be formed on a substrate 60. The substrate 60 may be, for example, an n-type semiconductor substrate. First and second contact holes h11 and h22 may be formed in the first insulating interlayer 62, to respectively expose different portions of the substrate 60. The first contact hole h11 may be filled with a first conductive plug 66, and the second contact hole h22 may be filled with a second conductive plug 68. The first and second conductive plugs 66 and 68 may be composed of different materials. For example, the first conductive plug 66 may be composed of the same semiconductor material as that of the substrate 60, for example, a plug composed of n-type silicon. Doped densities of the substrate 60 and the first conductive plug 66 may be different. Also, the second conductive plug 68 may be a metal plug. The second conductive plug 68 may be a plug composed of the same polarity of semiconductor as that of the substrate 60. A first interconnection 70 and a phase change layer 74 may be separately disposed on the first insulating interlayer 62.

An upper electrode 76 may be formed on the phase change layer 74. The upper electrode 76 may be any one selected from the group of Ti—N, Ti—Al—N, W—N, Ti—W, and Ti—Te electrodes or may be composed of at least two electrodes thereof. The first interconnection 70 may contact the second conductive plug 68. The first interconnection 70 may function as a word line, and may be composed of the same material as that of the first interconnection 42 of FIG. 2A. The phase change layer 74 may have a p-type semiconductor property, and may be the same material as that of the phase change layer 48 of FIG. 2A. The phase change layer 74 and a first conductive plug 66 may form a PN junction diode. The phase change layer 74 may contact the first conductive plug 66.

A second insulating interlayer 72 may be formed on the first insulating interlayer 62, to cover the first interconnection 70 and expose only the upper surface of the upper electrode 76. The second insulating interlayer 72 may be composed of the same material as that of the first insulating interlayer 62. A second interconnection 78 may be disposed on the second insulating interlayer 72. The second interconnection 78 may be disposed to extend in the direction crossing the first interconnection 70, for example, perpendicularly to the first interconnection 70. The second interconnection 78 may contact the upper surface of the upper electrode 76. The second interconnection 78 may be used as a bit line.

FIG. 4 illustrates a structure of the PRAM having the equivalent circuit of FIG. 1 according to example embodiments. Referring to FIG. 4, first and second stack structures S1 and S2 may be disposed on a substrate 60. The substrate 60 may be an n-type semiconductor substrate or an n-type doping region of a p-type semiconductor substrate, for example, an n-type well. The first and second stack structures S1 and S2 may be spaced from each other. The first stack structure S1 may include a lower electrode contact layer 80, a phase change layer 82, and an upper electrode 84, which may be sequentially stacked. The second stack structure S2 may include a first conductive plug 86 and a first interconnection 88, which may be sequentially stacked. The material and function of the lower electrode contact layer 80 may be the same as those of the first conductive plug 66 of FIG. 3.

The first conductive plug 66 of FIG. 3 may be formed by using a chemical vapor deposition method, but the lower electrode contact layer 80 of the first stack structure S1 may be formed using a selective epitaxial growth method. The phase change layer 82 and the upper electrode 84 of the first stack structure S1 may be formed using, for example, a CVD method, and materials and functions of the phase change layer 82 and the upper electrode 84 may be respectively the same as those of the phase change layer 74 and the upper electrode 76 of FIG. 3. The phase change layer 82 and the lower electrode contact layer 80 of the first stack structure S1 may have the same characteristics as that of a PN junction diode. Materials and functions of the first conductive plug 86 and the first interconnection 88 of the second stack structure S2 may be respectively the same as those of the conductive plug 68 and the first interconnection 70 of FIG. 3. The first interconnection 88 may function as a word line and/or a lower electrode.

An insulating interlayer 90 may be formed on the substrate 60, to cover the second stack structure S2 and expose only an upper surface of the upper electrode 84 of the first stack structure S1. The insulating interlayer 90 may be the same as that of the first insulating interlayer 62 of FIG. 3. A second interconnection 98 may be disposed on the insulating interlayer 90, to contact the upper surface of the upper electrode 84 of the first stack structure S1. The second interconnection 98 may be used as a bit line and may be disposed to extend in the direction crossing the first interconnection 88.

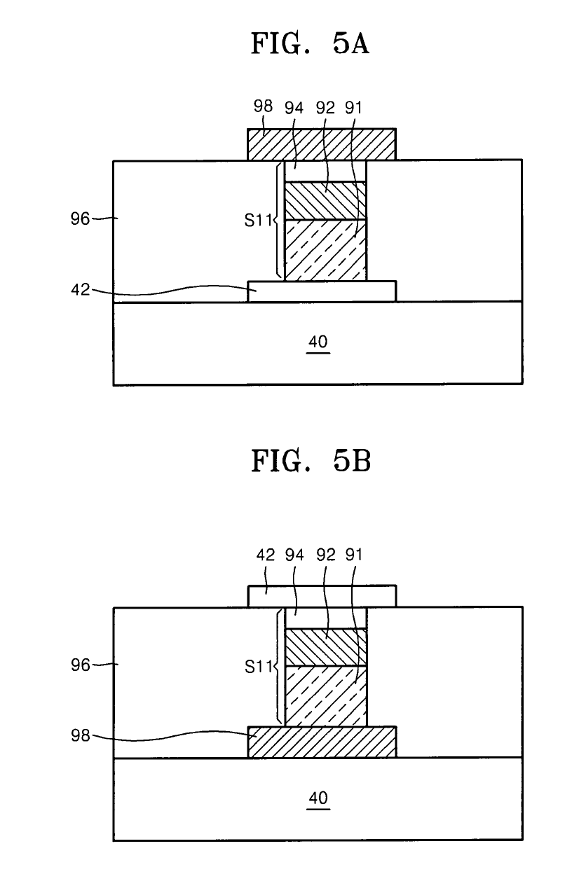

FIGS. 5A and 5B illustrate examples of PRAMs, in which technical characteristics of the PRAM according to example embodiments in FIG. 4 may be employed in the PRAM according to example embodiments in FIG. 2A. Referring to FIG. 5A, a first interconnection 42 functioning as a word line and a lower electrode may be disposed on a substrate 40. A stack structure S11 may be disposed on the first interconnection 42. The stack structure S11 may include a lower electrode contact layer 91, a phase change layer 92 and an upper electrode contact plug 94, which may be sequentially stacked. The lower electrode contact layer 91 may be an n-type silicon layer. The phase change layer 92 may be a phase change material layer showing the same characteristics as that of a p-type semiconductor, for example, a GST layer.

The upper electrode contact plug 94 may be, for example, a titanium electrode. An insulating interlayer 96 may be formed on the substrate 40 to cover the first interconnection 42 and around the upper electrode contact plug 94 of the stack structure S11 to expose an upper surface of the upper electrode contact plug 94. A second interconnection 98 may be formed on the insulating interlayer 96, to contact the upper surface of the upper electrode contact plug 94. The second interconnection 98 may be used as a bit line, and may cross the first interconnection 42 or be parallel to the first interconnection 42. Positions of the first and second interconnections 42 and 98 may be interchanged as shown in FIG. 5B. The second interconnection 98 may be disposed between the substrate 40 and the lower electrode contact layer 98. The first interconnection 42 may be disposed on the insulating interlayer 96, to cover the upper electrode contact plug 94. In this structure, the first and second interconnections 42 and 98 may cross each other and/or parallel to each other.

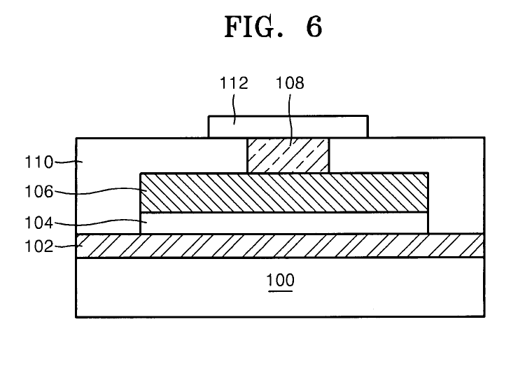

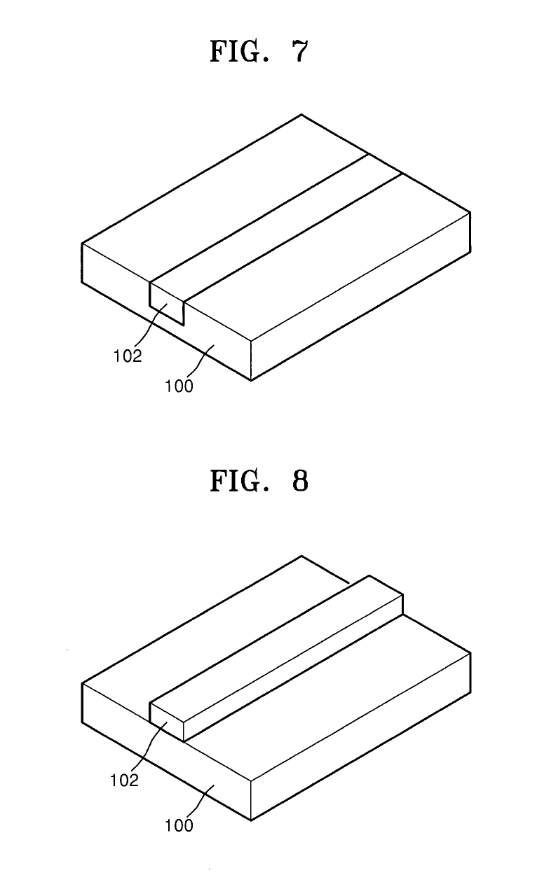

FIG. 6 illustrates a structure of a PRAM having the equivalent circuit of FIG. 1 according to example embodiments. In the PRAM according to example embodiments in FIG. 6, the positions of a phase change layer and a lower electrode contact layer may be changed. Referring to FIG. 6, a first interconnection 102 may be formed on a substrate 100. The first interconnection 102 may function as a bit line. The first interconnection 102 may be formed using a damascene process. As shown in FIG. 7, the first interconnection 102 may be buried in the substrate 100, except for its upper surface. Alternatively, the first interconnection 102 may be embossed on a predetermined or given portion of the substrate 100 as shown in FIG. 8. A first conductive layer 104 may be disposed on a predetermined or given portion of the first interconnection 102. The first conductive layer 104 may correspond to the upper electrodes 50, 76, 84, and 94 of the PRAM according to example embodiments. The first conductive layer 104 may be, for example, a titanium layer. The first conductive layer 104 may extend on the substrate 100.

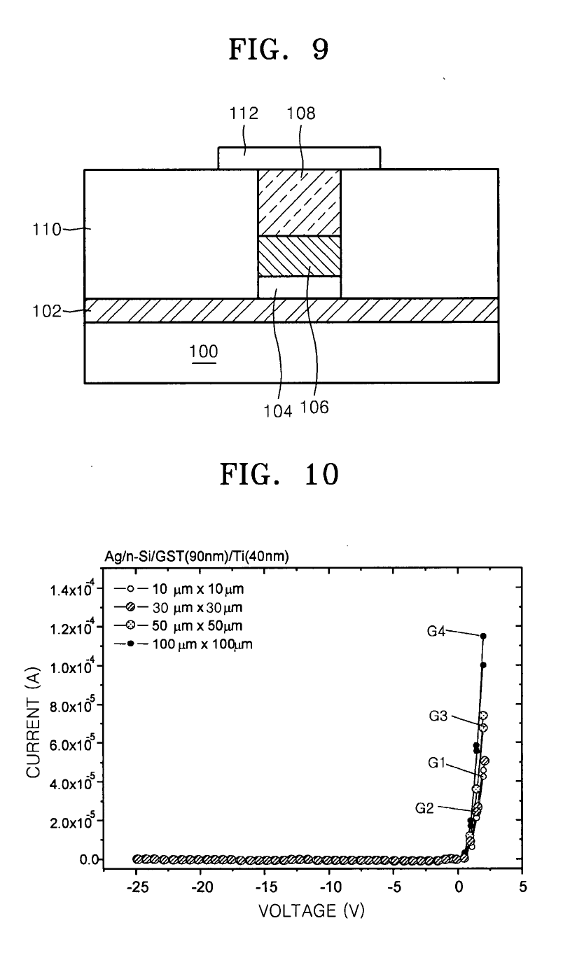

A phase change layer 106 may be disposed on the first conductive layer 104. The phase change layer 106 may have the same characteristics as that of a p-type semiconductor, and may be, for example, a GST layer. A conductive plug 108 may be disposed on a predetermined or given portion of the phase change layer 106. The conductive plug 108 may be a silicon plug doped with an n-type semiconductor material, for example, n-type impurities (e.g., phosphorus (P)). An insulating interlayer 110 may be formed on the substrate 100 to cover the line-shaped first interconnection 102, the first conductive layer 104, the phase change layer 106, and the conductive plug 108 to expose an upper surface of the conductive plug 108. A second interconnection 112 may be disposed on the insulating interlayer 110 to contact the upper surface of the conductive plug 108. The second interconnection 112 may function as a word line and/or an upper electrode and may cross the first interconnection 102. The first conductive layer 104, the phase change layer 106, and the conductive plug 108 may have a same diameter as shown in FIG. 9.

Current-voltage characteristics of the stack structure may be measured in order to verify whether the stack structure including the lower electrode contact layer and the phase change layer in the PRAM according to example embodiments described above shows P-N junction diode characteristics or not. There may be four specimens that may be fabricated to have same composition. The stack structure may include a silver (Ag) layer, an n-type silicon layer, a GST layer (about 90 nm thickness) and/or a titanium layer (about 40 nm thickness), which may be sequentially stacked. The size (transverse×longitudinal) of the stack structure may be different in each specimen. For example, a size of the stack structure of a first specimen may be about 10 μm×10 μm, a size of the stack structure of a second specimen may be about 30 μm×30 μm, a size of the stack structure of a third specimen may be about 50 μm×50 μm, and a size of the stack structure of a fourth specimen may be about 100 μm×100 μm. In the process of fabricating the stack structure of each specimen, a natural oxide layer (SiO₂) may be formed on an n-type silicon layer, but because a thickness of the natural oxide layer is relatively thin, the natural oxide layer may not influence current-voltage characteristics of the stack structure.

FIG. 10 illustrates current-voltage characteristics measured with respect to the four specimens. In FIG. 10, first through fourth plots (G1˜G4) respectively show current-voltage characteristics in the first through fourth specimens. In the current-voltage characteristics measurements, a voltage may be applied between an upper electrode and a lower electrode such that a current flows from the upper electrode (Ti layer) to the lower electrode (Ag layer). Referring to FIG. 10, although current intensities in the four specimens may be different in accordance with the sizes of the stack structures in the four groups when an applied voltage exceeds a threshold voltage, it may be acknowledged that the first through fourth specimens all show PN-junction diode characteristics.

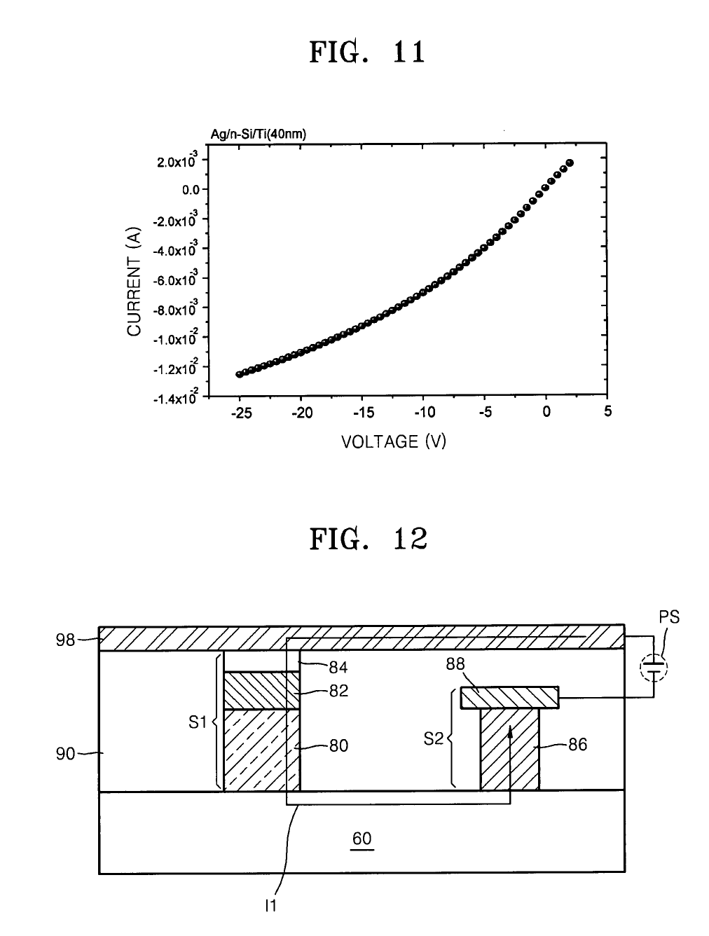

FIG. 11 illustrates current-voltage characteristics of the stack structure in the second specimen from which a GST layer as a phase change layer may be removed. Comparing FIG. 11 with the second plots (G2) in FIG. 10, it may be acknowledged that the plot of FIG. 11 may be different from the plot of the PN-junction diode characteristic. The result of FIG. 11 says that the GST layer in the stack structure of the second specimen may have the same characteristics as that of a p-type semiconductor. Because the stack structures of the first through fourth specimens are all the same in structure, and they all show the same PN-junction diode characteristics although their sizes may be different from one another, it may be acknowledged that current-voltage characteristics of the stack structures in the first, third, and fourth specimens, from which the GST layers are respectively removed, may be the same as that of the plot in FIG. 11.

A method of operating the PRAM according to example embodiments as described above will be explained. As the base structures of the PRAMs according to example embodiments as described above are the same, a method of operating the PRAM according to example embodiments, for example, the example embodiments of FIG. 4, will be explained, and methods of operating the PRAMs according to other example embodiments may be explained by the method of operating the PRAM of FIG. 4.

Referring to FIG. 12, a power source PS may be connected between a second interconnection 98 used as a bit line, and a first interconnection 88 functioning as a word line and a lower electrode. An insulating interlayer 90 may be formed on the substrate. A negative voltage may be applied from the power source PS through the first interconnection 88, the first conductive plug 86, and the substrate 60, to the lower electrode contact layer 80 composed of an n-type semiconductor material, and a positive voltage may be applied to the upper electrode 84 through the second interconnection 98. A forward current I1 flows through the first stack structure S1. When the condition of a current applied between the first interconnection 88 and the second interconnection 98 satisfies a reset current condition, because the forward current I1 may be higher than the reset current Ireset, a portion of the first stack structure S1 in contact with the lower electrode contact layer 80 of the phase change layer 82 may be phase-changed from a crystal state to an amorphous state.

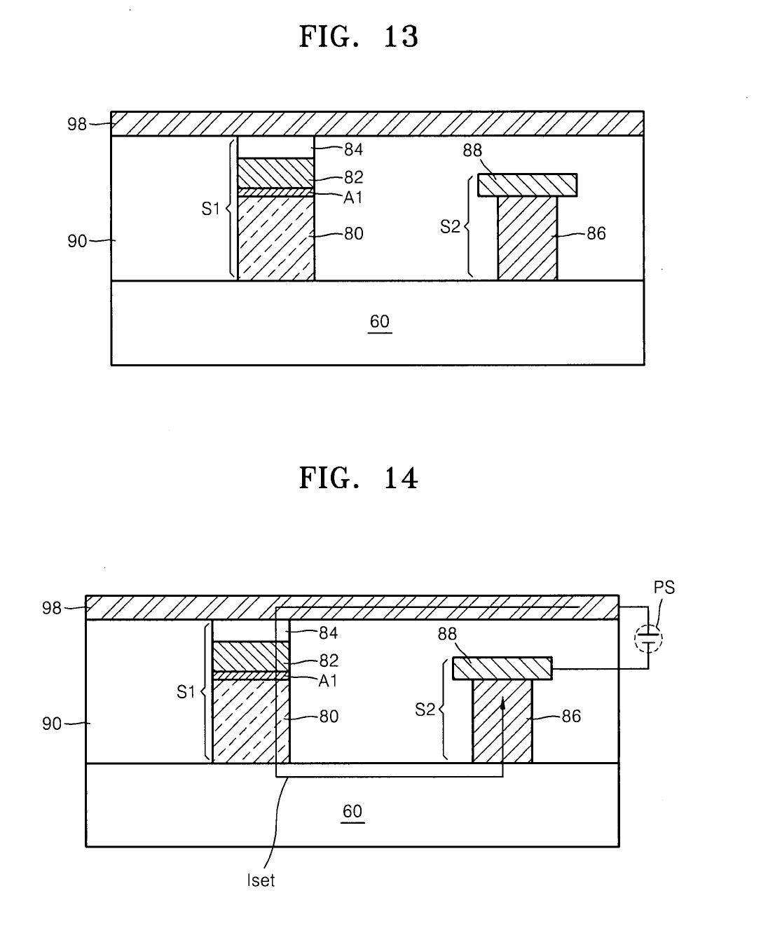

As shown in FIG. 13, the phase change layer 82 of the first stack structure S1 may have an amorphous region A1 at the interface in contact with the lower electrode contact layer 80. Because the amorphous region A1 is formed in the phase change layer 82 as above, a resistance of the first stack structure S1 may be higher than that of the first stack structure S1 before the amorphous region A1 is formed. Data 1 may be recorded to the PRAM of example embodiments when a resistance of the first stack structure S1 increases. When a forward current I1 is higher than a reset current Ireset, the applied voltage may be a write voltage.

As shown in FIG. 14, when a set current Iset flows in a forward direction to the phase change layer 82 of the first stack structure S1 having the amorphous region A1, the amorphous region A1 in the phase change layer 82 may be changed to a crystal region. Because the entire phase change layer 82 has a crystal structure, a resistance of the first stack structure S1 may decrease compared to a resistance when the amorphous region A1 exists in the phase change layer 82. The process of changing the amorphous region A1 in the phase change layer 82 to a crystal region so as to decrease the resistance of the first stack structure may be a process of erasing the data recorded in the PRAM of the example embodiments. A voltage applied between the first and second interconnections 88 and 98 so that a set current Iset flows to the first stack structure S1 in a forward direction may be an erase voltage.

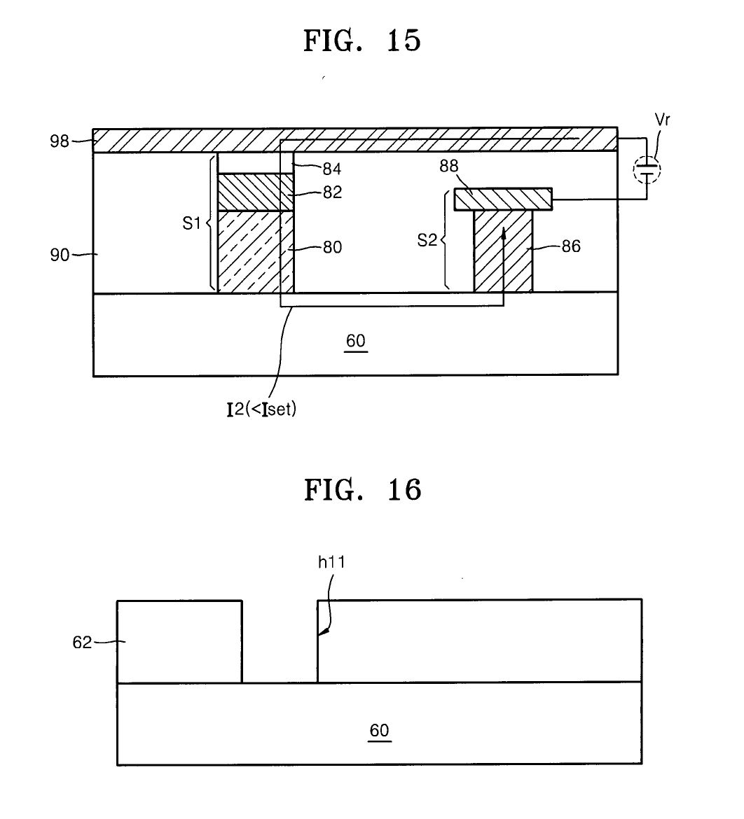

A read operation in the PRAM of example embodiments may use the characteristics that a resistance of the first stack structure S1 may be varied whether the amorphous region A1 exists in the phase change layer 82 of the first stack structure S1 or not. Referring to FIG. 15, a predetermined or given read voltage Vr may be applied between the first and second interconnections 88 and 98. A forward current 12 may flow to the first stack structure S1, and the forward current I2 may be lower than a set current Iset. A resistance of the first stack structure S1 may be measured by flowing a forward current 12 to the first stack structure S1. The measured resistance may be compared to a reference resistance. The reference resistance may have an intermediate value between a resistance of the first stack structure S1 when an amorphous region may exist in the phase change layer 82, and a resistance of the first stack structure S1 when an amorphous region may not exist in the phase change layer 82. When the measured resistance is lower than the reference resistance, data 0 may be read when the amorphous region may not exist in the phase change layer 82. On the contrary, when the measured resistance is higher than the reference resistance, data 1 may be read when the amorphous region may exist in the phase change layer 82.

A method of fabricating a PRAM according to example embodiments will be explained. Referring to FIG. 16, a first insulating interlayer 62 may be formed on a substrate 60. The substrate 60 may be an n-type semiconductor substrate. An n-well formed by doping a p-type semiconductor substrate with n-type impurities, for example, phosphorus, may be used for the substrate 60. A first contact hole h11 may be formed in the first insulating interlayer 62 to expose the substrate 60 using a photolithography process and an etch process.

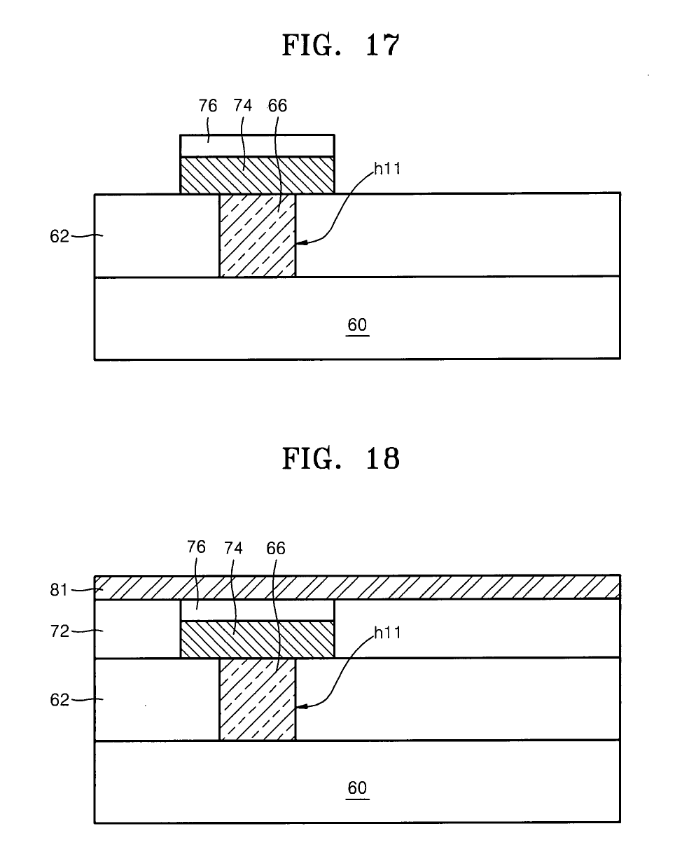

Referring to FIG. 17, the first contact hole h11 may be filled with a first conductive plug 66. The first conductive plug 66 may be composed of an n-type semiconductor material, for example, an n-Si. A phase change layer 74 and an upper electrode 76 may be sequentially formed on the first insulating interlayer 62 to cover an exposed portion of the first conductive plug 66. The phase change layer 74 and the upper electrode 76 may be formed by sequentially stacking respective formation material layers, and etching the respective formation material layers in a reverse order using a mask defining a shape of the phase change layer 74, and removing the mask. The phase change layer 74 may have a p-type semiconductor material characteristic, and may be formed of, for example, one of a Ge₂Sb₂Te₅ layer, a GeSb₂Te₄ layer, a Te—Ge—Sn—Au layer, a GeTe—Sb₂Te₃ layer, an In₃SbTe₂ layer, a GeTe—Sb₂Te₃—Sb layer, a Ge—Sb—Te—Pd layer, a Ge—Sb—Te—Co layer or a Sb₂Te₃—Bi₂Se₃ layer. The phase change layer 74 may be formed using a CVD process and/or other methods. The upper electrode 76 may be a metal electrode, for example, a titanium electrode.

Referring to FIG. 18, a second insulating interlayer 72 may be formed on the first insulating interlayer 62, to cover the phase change layer 74 and the upper electrode 76, and the second insulating interlayer 72 may be planarized, using a CMP process or other polishing methods. The planarization process may be performed until the upper electrode 76 is exposed. The second insulating interlayer 72 may be composed of the same material as that of the first insulating interlayer 62. After the planarization process, a conductive layer (not shown) may be formed on the second insulating interlayer 72. The conductive layer may be patterned in a line shape using a photolithography process and/or an etch process. As a result, a bit line 81 may be formed on the second insulating interlayer 72.

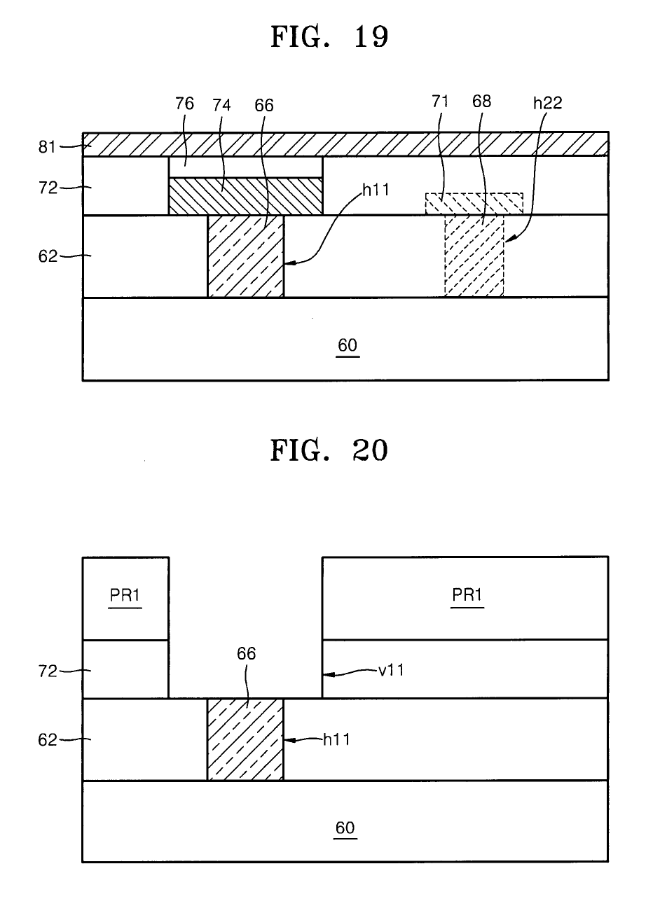

Referring to FIG. 19, a second contact hole h22 may be formed to be spaced from the first contact hole h11 of the first insulating interlayer 62, to expose the substrate 60. The second contact hole h22 may be filled with a second conductive plug 68. The second conductive plug 68 may be composed of a doped silicon and/or metal. A conductive line 71 may be formed on the first insulating interlayer 62 to cover an exposed portion of the second conductive plug 68. The conductive line 71 may be formed in the direction crossing the bit line 81. The conductive line 71 may be used as a word line and/or a lower electrode. The conductive line 71 may correspond to the first interconnection 70 of FIG. 3, and the bit line 81 may correspond to the second interconnection 78.

Because the second contact hole h22, the second conductive plug 68, and the conductive line 71 are formed either in back or front of the sectional view of FIG. 19, they may be illustrated in dotted lines for convenience. Alternatively, after the first contact hole h11 of the first insulating interlayer 62 is filled with the first conductive plug 66, a second via hole h22 may be formed in the first insulating interlayer 62 with a portion covering the first contact plug 66 masked, and the second contact hole h22 may be filled with the second conductive plug 68. The phase change layer 74 and the upper electrode 76 may be formed, using other methods than the method described above, for example, a damascene process.

As shown in FIG. 20, a photoresistive layer pattern PR1, defining a portion for the phase change layer 74 to be formed, may be formed in the second insulating interlayer 72. The second insulating interlayer 72 may be etched, using the photoresistive layer pattern PR1 as an etch mask. The etch may be performed until the first conductive plug 66 is exposed. As a result of the etch, a via hole v11 may be formed in the second insulating interlayer 72, to expose an upper surface of the first conductive plug 66, and expose a portion of the second insulating interlayer 72 around the first conductive plug 66.

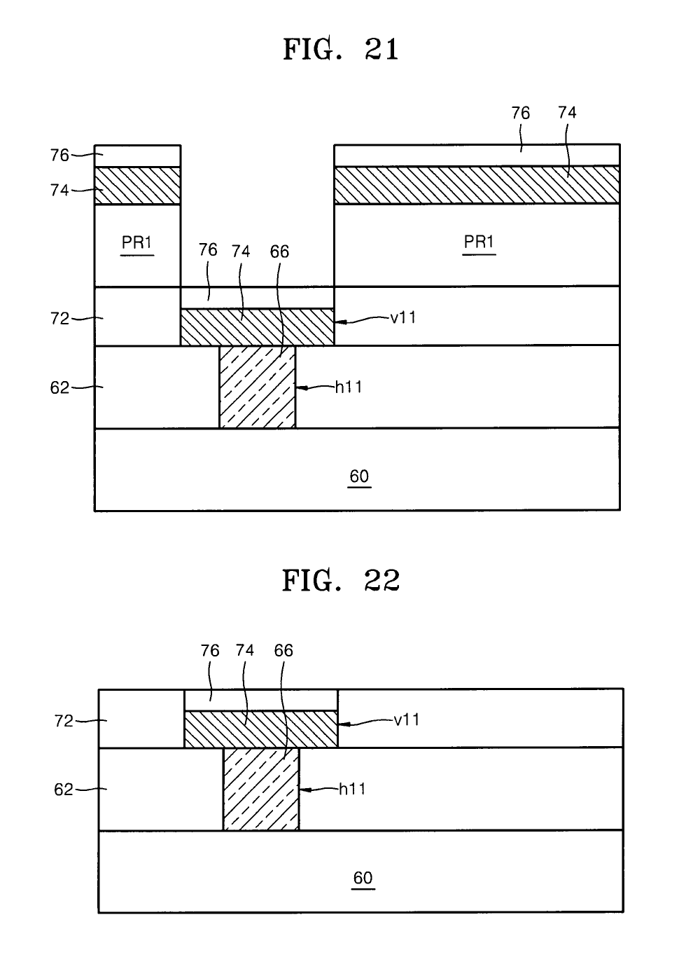

Referring to FIG. 21, a portion of the via hole v11 may be filled with the phase change layer 74 at a predetermined or given height. During the process, the phase change layer 74 may also be formed on the photoresistive layer pattern PR1. A rest portion of the via hole v11, which is filled with the phase change layer 74, may be filled with an upper electrode 76. The upper electrode 76 may also be formed on the phase change layer 74, which is formed on the photoresistive layer pattern PR1. The photoresistive layer pattern PR1 may be removed. While the photoresistive layer pattern PR1 is removed, the phase change layer 74 and the upper electrode 76, which are formed on the photoresistive layer pattern PR1, may also be removed. As shown in FIG. 22, the via hole v11 may be filled by sequentially stacking the phase change layer 74 and the upper electrode 76. Subsequent processes may be the same as described in reference to FIGS. 18 and 19.

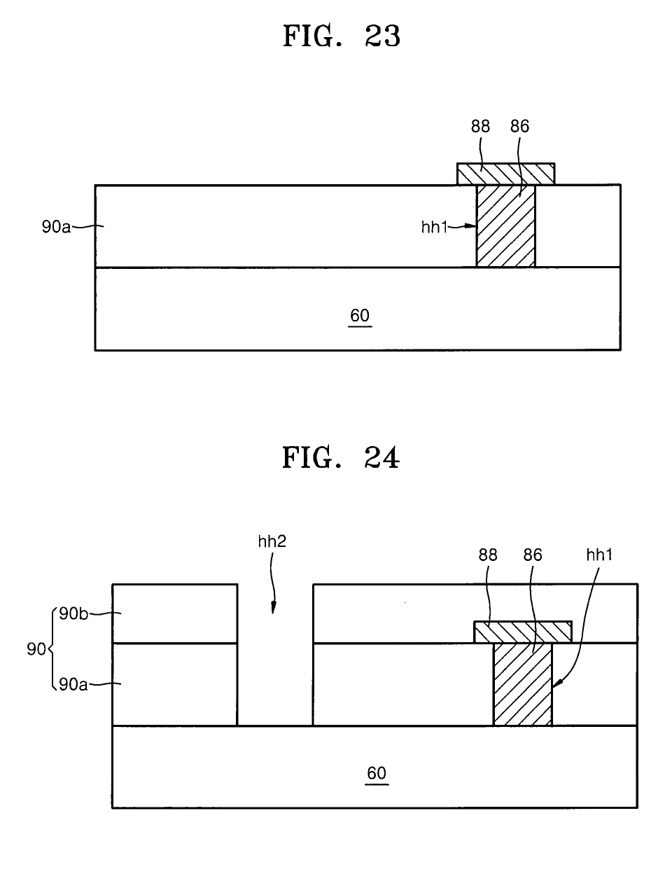

A method of fabricating the PRAM according to example embodiments in FIG. 4 will be explained. Referring to FIG. 23, a first insulating interlayer 90a may be formed on the substrate 60. A first contact hole hh1 may be formed in the first insulating interlayer 90a to expose the substrate 60. The first contact hole hh1 may be filled with a first conductive plug 86. The first conductive plug 86 may be formed of a doped silicon layer or a conductive layer. A first interconnection 88 may be formed on the first insulating interlayer 90a to cover the first conductive plug 86. The first interconnection 88 may be used as a word line and/or a lower electrode.

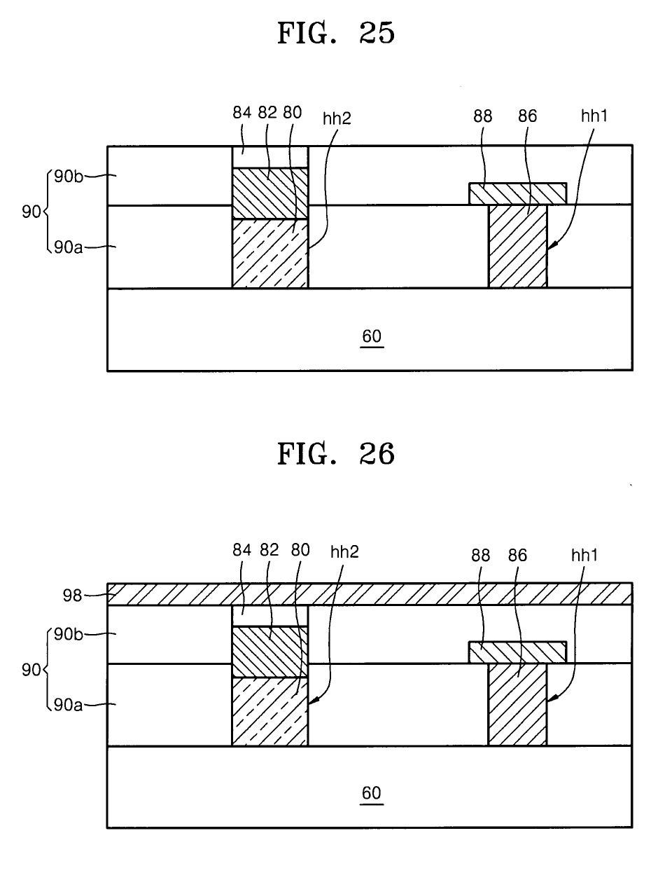

Referring to FIG. 24, a second insulating interlayer 90b may be formed on the first insulating interlayer 90a to cover the first interconnection 88. A second contact hole hh2 may be formed in the insulating interlayer 90, which may include the first and second insulating interlayers 90a and 90b, to expose the substrate 60. Referring to FIG. 25, a portion of the second contact hole hh2 may be filled with a lower electrode contact layer 80 at a predetermined or given height. The lower electrode contact layer 80 may be an n-type silicon layer grown only on the substrate 60 exposed through the second contact hole hh2, using a selective epitaxial growth method. The n-type silicon layer may be formed by doping n-type impurities, for example, phosphorus (P), during the process of growing the silicon layer using the selective epitaxial growth method. After a portion of the second contact hole hh2 is filled with the lower electrode contact layer 80 as above, a rest portion of the second contact hole hh2 may be filled by sequentially stacking the phase change layer 82 and the upper electrode 84. The phase change layer 82 and/or the upper electrode 84 may be formed using a CVD method. After the second contact hole hh2 is filled, a second interconnection 98 may be formed on the insulating interlayer 90 as shown in FIG. 26. The second interconnection 98 may be used as a bit line and may cross the first interconnection 88.

The PRAM according to example embodiments of FIGS. 2A and 5A may be fabricated by forming the first interconnection 88 between the substrate 60 and the lower electrode contact layer 80, and using the first interconnection 88 as a word line and a lower electrode, instead of forming the first conductive plug 86 and the first interconnection 88. The PRAM according to example embodiments of FIGS. 6 and 9 may be formed using the same processes according to other example embodiments except for forming a bit line below a word line, and forming the phase change layer below the lower electrode contact layer.

In the many PRAMs according to example embodiments as described above, a phase change material showing n-type semiconductor characteristics, for example, In—S, Ti—In—S, and/or Ge—Bi—Te, may be used for the phase change layers 48, 74, 82, 92, and 106, instead of using the phase change material showing p-type semiconductor characteristics, for example, GST. The lower electrode contact layers 46, 66, 80, 90 and 108 of the PRAMs of example embodiments as described above may be composed of a semiconductor material doped with p-type impurities, for example, p-Si. An applied voltage for operation may be applied reversely to the above. For example, a negative voltage may be applied to the phase change layer, and a positive voltage may be applied to the lower electrode contact layers.

In the PRAMs and the methods of fabricating the same according to example embodiments as described above, a doping density of a lower electrode contact layer may be provided variously in accordance with regions. For example, an impurity doping density may be provided to sequentially increase and/or decrease from a bottom end of the lower electrode contact layer to a top end thereof and/or from a top end to a bottom end. Example embodiments have been described specifically as above, but it must be understood that example embodiments do not limit the scope of example embodiments. For example, the phase change layer and/or the lower electrode contact layer may be formed using other materials than the materials described above by those skilled in this art. An operation current may be decreased by reducing sizes of the elements while keeping the same technical spirit of example embodiments. A material layer may be further provided between the substrate and the lower electrode contact layer, or between the upper electrode and the bit line to decrease a contact resistance. The scope of example embodiments may be determined by the technical spirit defined in claims rather than the embodiments described above.

As described above, because the phase change layer in the PRAM of example embodiments has p-type semiconductor material characteristics or a n-type semiconductor material characteristic, the stack structure including the phase change layer may be a resistance element and also may have a diode function. Because a separate switching element (for example, a transistor or a diode) for controlling current flow is not necessary when the PRAM of example embodiments is used, the structure of the PRAM may be simplified. Fabrication processes of the PRAM may be simplified, and an integration density thereof may be increased.

While example embodiments have been particularly shown and described with reference to example embodiments thereof, it will be understood by those of ordinary skill in the art that various changes in form and details may be made therein without departing from the spirit and scope of the following claims.

What is claimed is:

1. A phase change RAM (PRAM) comprising:
a substrate;
a phase change diode layer on the substrate; and
an upper electrode on the phase change diode layer.

2. The PRAM of claim 1, wherein the phase change diode layer includes:
a material layer doped with first impurities, and a phase change layer, which are sequentially stacked, wherein the phase change layer shows characteristics of a semiconductor material doped with impurities having an opposite conductive type to that of the first impurities.

3. The PRAM of claim 2, wherein the first impurities are p-type impurities, and the phase change layer is composed of a phase change material showing n-type semiconductor material characteristics.

4. The PRAM of claim 2, wherein the first impurities are n-type impurities, and the phase change layer is composed of a phase change material showing p-type semiconductor material characteristics.

5. The PRAM of claim 2, wherein a width of the phase change layer is greater than a width of the material layer doped with first impurities.

6. The PRAM of claim 5, wherein the substrate is a non-semiconductor substrate.

7. The PRAM of claim 4, wherein a width of the phase change layer is greater than a width of the material layer doped with first impurities.

8. The PRAM of claim 2, further comprising:
a word line between the phase change diode layer and the substrate; and
a bit line on the upper electrode to contact the upper electrode and cross the word line.

9. The PRAM of claim 8, wherein a width of the phase change layer is greater than a width of the material layer doped with first impurities.

10. The PRAM of claim 2, further comprising:
a word line on the substrate spaced from the phase change diode layer: and
a bit line on the upper electrode to contact the upper electrode and to cross the word line.

11. The PRAM of claim 10, wherein the first impurities are p-type impurities, and the phase change layer is composed of a phase change material showing a n-type semiconductor material characteristic.

12. The PRAM of claim 1, wherein the phase change diode layer includes:
a phase change layer and a material layer doped with first impurities, which are sequentially stacked, in which the phase change layer is composed of a phase change material showing characteristics of a semiconductor material doped with impurities having an opposite conductive type to that of the first impurities.

13. The PRAM of claim 12, wherein the first impurities are n-type impurities, and the phase change layer is composed of a phase change material showing p-type semiconductor material characteristics.

14. The PRAM of claim 13, wherein a width of the phase change layer is greater than a width of the material layer doped with first impurities.

15. The PRAM of claim 12, wherein a width of the phase change layer is greater than a width of the material layer doped with first impurities.

16. The PRAM of claim 13, wherein the substrate is a non-semiconductor substrate.

17. The PRAM of claim 12, further comprising:
a bit line between the phase change diode layer and the substrate; and
a word line on the upper electrode to contact the upper electrode and to cross the bit line.

18. The PRAM of claim 12, further comprising:
a bit line on the substrate spaced from the phase change diode layer.

19. The PRAM of claim 17, wherein a width of the phase change layer is greater than a width of the material layer doped with first impurities.

20. The PRAM of claim 1, wherein the substrate is an n-type or a p-type semiconductor substrate.

21. A method of operating a PRAM comprising:
providing a phase change diode layer between a substrate and a first interconnection; and
applying a current through the phase change diode layer and between the substrate and the first interconnection in a forward direction.

22. The method of claim 21, wherein applying the current includes applying a write current.

23. The method of claim 21, wherein applying the current includes applying a read current.

24. The method of claim 23, wherein applying the read current includes:
applying the read current to measure a resistance of the phase change diode layer; and
comparing the measured resistance to a reference resistance.

25. The method of claim 21, wherein applying the current includes applying an erase current.

26. The method of claim 21, wherein the phase change diode layer includes a material layer doped with first impurities and a phase change layer, which are sequentially stacked, wherein the phase change layer is composed of a phase change material showing characteristics of a semiconductor material doped with impurities having an opposite conductive type to that of the first impurities.

27. The method of claim 26, wherein a second interconnection is further provided between the substrate and the phase change diode layer, and the current is applied between the first interconnection and the second interconnection.

28. The method of claim 26, wherein a second interconnection is further provided on a portion of the substrate spaced from the phase change diode layer, and the current is applied between the first interconnection and the second interconnection.

29. The method of claim 21, wherein the phase change diode layer includes a phase change layer and a material layer doped with first impurities, which are sequentially stacked, wherein the phase change layer is composed of a phase change material showing characteristics of a semiconductor material doped with impurities having an opposite conductive type to that of the first impurities.

30. The method of claim 29, wherein a second interconnection is further provided between the substrate and the phase change diode layer, and the current is applied between the first interconnection and the second interconnection.

31. The method of claim 29, wherein a second interconnection is further provided on a portion of the substrate spaced from the phase change diode layer, and the current is applied between the first interconnection and the second interconnection.

32. The method of claim 21, wherein a second interconnection is further provided between the substrate and the phase change diode layer, and the current is applied between the first interconnection and the second interconnection.

33. The method of claim 21, wherein a second interconnection is further provided on a portion of the substrate spaced from the phase change diode layer, and the current is applied between the first interconnection and the second interconnection.

34. A method of fabricating a PRAM comprising:
forming a first interconnection on a substrate doped with first impurities;
forming a first insulating interlayer on the substrate to cover the first interconnection;
exposing a portion of the substrate spaced from the first interconnection by forming a contact hole in the first insulating interlayer;
filling the contact hole with a material layer doped with first impurities;
sequentially stacking a phase change layer and an upper electrode on the first insulating interlayer to cover the doped material layer, the phase change layer showing semiconductor characteristics opposite to that of the doped material layer; and
forming a second interconnection connected to the upper electrode and crossing the first interconnection.

35. The method of claim 34, wherein sequentially stacking includes:
forming a second insulating interlayer on the first insulating interlayer to cover the doped material layer;
forming a photoresistive layer pattern on the second insulating interlayer defining a portion where the phase change layer is formed;
exposing the doped material layer in the second insulating interlayer by forming a via hole using the photoresistive layer pattern as a mask;
sequentially stacking the phase change layer and the upper electrode in the via hole; and
removing the photoresistive layer pattern.

36. The method of claim 34, wherein the first impurities are n-type impurities, and the phase change layer is composed of a phase change material showing a p-type semiconductor material characteristic.

37. A method of fabricating a PRAM comprising:
forming a first interconnection on a substrate doped with first impurities;
forming an insulating interlayer on the substrate to cover the first interconnection;
exposing a portion of the substrate spaced from the first interconnection by forming a contact hole in the insulating interlayer;
sequentially stacking a material layer doped with the first impurities, a phase change layer showing semiconductor characteristics opposite to that of the doped material layer, and an upper electrode in the contact hole; and
forming a second interconnection on the insulating interlayer, the second interconnection connected to the upper electrode and crossing the first interconnection.

38. The method of claim 37, wherein the first impurities are n-type impurities, and the phase change layer is composed of a phase change material showing a p-type semiconductor material characteristic.

39. The method of claim 37, wherein the material layer doped with the first impurities, and the phase change layer are formed using different methods.

40. The method of claim 37, wherein the material layer doped with the first impurities is formed using a selective epitaxial growth method.

41. A method of fabricating a PRAM comprising:
forming a first interconnection on a substrate;
forming an insulating interlayer on the substrate to cover the first interconnection;
exposing a portion of the first interconnection by forming a contact hole in the insulating interlayer;
forming a conductive layer, a phase change layer and a material layer doped with first impurities in the contact hole; and
forming a second interconnection connected to the doped material layer and crossing the first interconnection on the insulating interlayer, wherein the phase change layer is composed of a phase change material showing semiconductor characteristics opposite to that of the doped material layer.

42. The method of claim 41, wherein the first interconnection is formed to be buried in the substrate or embossed on the substrate.

43. A method of fabricating a PRAM comprising:
forming a first interconnection on a substrate doped with first impurities;
forming an insulating interlayer on the substrate to cover the first interconnection;
exposing a portion of the substrate spaced from the first interconnection by forming a contact hole in the insulating interlayer;
sequentially forming a phase change layer and a material layer doped with second impurities having a conductive type opposite to that of the first impurities in the contact hole; and
forming a second interconnection connected to the doped material layer and crossing the first interconnection on the insulating interlayer, wherein the phase change layer is composed of a phase change material showing the same semiconductor characteristics as that of the substrate.

44. The method of claim 43, further comprising:
forming a conductive layer between the substrate and the phase change layer.

45. The method of claim 43, further comprising:
forming a conductive plug between the first interconnection and the substrate.
